(19) United States
(12) Patent Application Publication
(10) Pub. No.: US 2026/0123323 A1
(43) Pub. Date: Apr. 30, 2026

(54) LIQUID CHEMICAL SUPPLY SYSTEM, MEASUREMENT SYSTEM AND RELATED METHODS

(71) Applicant: Taiwan Semiconductor Manufacturing Company Limited, Hsin-Chu (TW)

(72) Inventors: Fang-Pin CHIANG, Taichung City (TW); Kuan Chun LI, New Taipei City (TW); Yi-Lung CHUNG, Hsin-Chu (TW); Yu-Yuan PENG, New Taipei City (TW); Wei-I LIU, Hsinchu County (TW); Feng-An YANG, Hsinchu City (TW); Jie-Ming ZHENG, Yilan County (TW)

(21) Appl. No.: 18/926,398

(22) Filed: Oct. 25, 2024

(51) Int. Cl. H01L 21/67

(52) U.S. Cl. CPC H10P 72/0402

(57) ABSTRACT

A method is provided. The method includes: storing a liquid chemical in a storage tank; supplying the liquid chemical from the storage tank to a semiconductor processing tool; obtaining a first sample of the liquid chemical from a first apparatus in fluid communication with the storage tank via a liquid selection apparatus; measuring a first level of particles in the first sample by a liquid particle counter (LPC); after obtaining the first sample, obtaining a second sample of the liquid chemical from a second apparatus in fluid communication with the storage tank via the liquid selection apparatus, the second apparatus being different than the first apparatus; and measuring a second level of particles in the second sample by the LPC.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic view of a system for supplying a material, in accordance with some embodiments.

FIG. 1B illustrates a detailed schematic view of the system, in accordance with some embodiments.

FIG. 2 illustrates a detailed schematic view of a liquid selection apparatus of the system, in accordance with some embodiments.

FIG. 3 illustrates a schematic view of a measurement system having a buffer tank, in accordance with some embodiments.

FIG. 4 illustrates a schematic view of a measurement system and a liquid selection apparatus, in accordance with some embodiments.

FIG. 5 illustrates a schematic view of a particle monitoring system, in accordance with some embodiments.

FIG. 6 is a flow diagram illustrating a method of operating a polishing liquid supply system, in accordance with some embodiments.

FIG. 7 is a flow diagram illustrating a method, in accordance with some embodiments.

FIG. 8 is a flow diagram illustrating a method, in accordance with some embodiments.

FIG. 9 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, a production line can be affected by contamination events associated with supply of liquid chemical materials, such as isopropyl alcohol (IPA), developers, etchants, cleaners, and the like. In advanced processing, particle size detection resolution has reached 19 nanometers (nm) or lower. On the other hand, detection resolution at materials suppliers and the factory floor remains at about 30 nm. Instability of liquid material entering a liquid particle counter (LPC) reduces measurement stability, which reduces material supply quality.

The LPC detects particles via optical refraction, which is increasingly difficulty, even with high performance optics. Thus, LPC measurement is very susceptible to interference from incoming material characteristics, such as bubbles in the liquid. Different LPC apparatuses operate using different flow rates, such as 10 cc/min, 35 cc/min, and the like. The measurement process benefits from stable pressure. Pressure of pulses generated by a pump can cause variations in measurements generated by the LPC.

In embodiments of the disclosure, differences between different measurement points can be canceled out and measurement conditions have increased stability and uniformity. Bubble interference is reduced by including a buffer tank that outputs the liquid chemical material to the LPC using a gas pressure method.

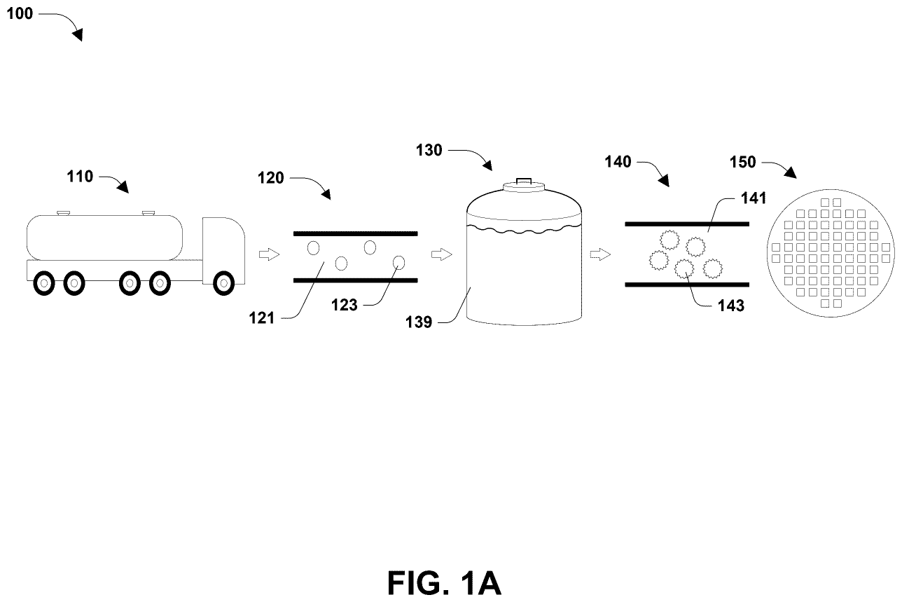

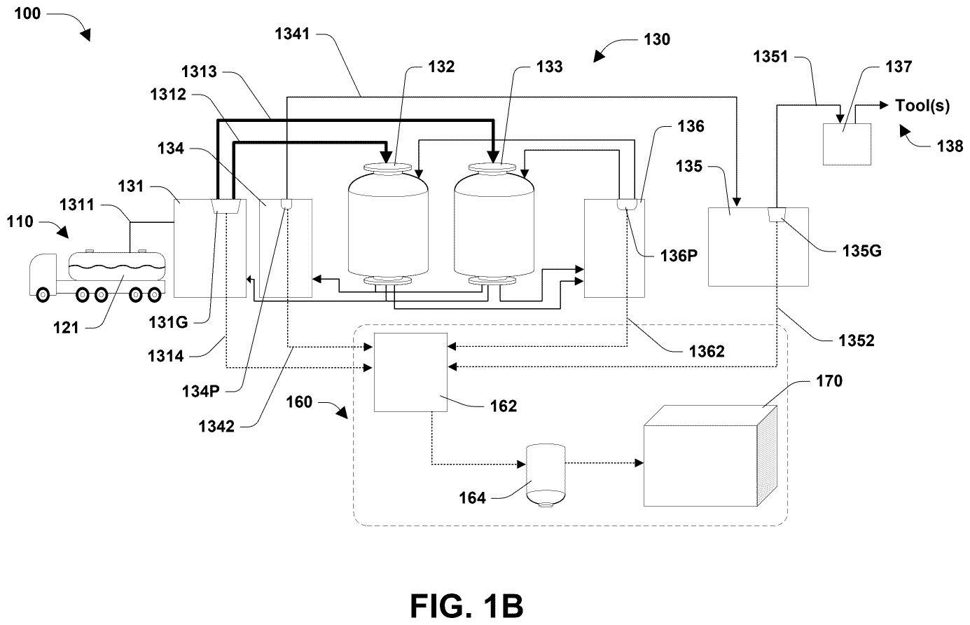

FIG. 1A illustrates a schematic view of a system 100 for supplying a material, in accordance with some embodiments. FIG. 1B illustrates a detailed schematic view of the system 100, in accordance with some embodiments.

In some embodiments, liquid chemicals 121 are transferred from a truck 110 to a factory supply system 130 through a process that can include one or more of preparation, connection, pumping, and monitoring. The truck 110 can be a tanker truck, for example, and may be positioned on a selected pad and grounded. Then, flexible hoses of a transport system 120 are connected between a discharge outlet(s) of the truck 110 and a tank of the factory supply system 130, and vapor recovery systems may optionally be used for volatile chemicals. A pump, either on the truck 110 or at the factory supply system 130, drives the liquid transfer, with flow controlled by valves and monitored by sensors to improve safe operation. Level of liquid chemical 121 in the factory supply system 130 can be monitored closely to prevent overfilling, and leak detection systems are optionally used. After the transfer, hoses can be drained, disconnected, and secured.

The factory supply system 130 can include one or more storage tanks, pumps, filtration systems, monitoring systems, quality measurement systems, and the like. Liquid chemicals 141 can be supplied from the storage tanks to online tools, such as etchers or cleaners, through a system of pipelines and pumps selected to provide uniform flow and pressure. The liquid chemicals 141 and the liquid chemicals 121 can be the same as or different than each other. In some embodiments, the liquid chemicals 141 supplied to the tools are substantially the same as the liquid chemicals 121 received from the truck 110. For example, the liquid chemicals 121, 141 can both be IPA. In some embodiments, the liquid chemicals 141 are different in one or more aspects from the liquid chemicals 121. For example, additives may be mixed in with the liquid chemicals 121 in the factory supply system 130 to form the liquid chemicals 141. In another example, the liquid chemicals 121 in the factory supply system 130 may be “aged” to form the liquid chemicals 141 via a chemical reaction that is allowed to proceed for a selected time. Aging can be performed on etchants (e.g., acids) prior to supplying to the tools, for example.

The pumps draw the chemical from the storage tanks and transport it through compatible pipelines, with valves and flow meters controlling and monitoring the flow. The pumps can be calibrated for the selected chemical. An example pipeline 140 is depicted in FIG. 1A. The liquid chemical 141 may pass through a filter(s) to remove particulates or “particles” 123 prior to being supplied to the tools, where the liquid chemicals 141 are introduced into process chambers. In some systems, excess liquid chemicals 141 are collected for reuse or waste treatment, providing safe and precise delivery of the liquid chemicals 141 to support the manufacturing process.

In some embodiments, the tools are operable to perform one or more semiconductor manufacturing process operations on a first semiconductor wafer 150. The first semiconductor wafer 150 comprises at least one of a substrate, a photomask, a semiconductor device, a dielectric layer, an epitaxial layer, a silicon-on-insulator (SOI) structure, a semiconductor layer, a conductive material layer, a die, etc. The first semiconductor wafer 150 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The first semiconductor wafer 150 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the first semiconductor wafer 150 are within the scope of the present disclosure.

As depicted in FIG. 1A, the liquid chemical 121 supplied to the factory supply system 130 from the truck 110 has particles 123 dispersed therein. When the liquid chemical 121 is transferred from the truck 110 to the factory supply system 130, the liquid chemical 121 may contain contaminants that are particulates 123, such as residual particles from previous loads, including dust, rust, or chemical remnants if the truck 110 was not properly cleaned. Environmental contaminants, such as dust or dirt can enter during the transfer from the truck 110 to the factory supply system 130, for example, if connections are not fully sealed. Small particles from hoses, fittings, or pipelines, such as rubber fragments, metal shavings, or corrosion byproducts, may be introduced. Contaminants from a manufacturing process that forms the liquid chemical 121, including trace impurities or packaging debris, and chemical degradation products formed during storage, can also contribute to particulate contamination depicted by the particles 123.

Then, when the liquid chemical 141 is supplied to the tools via the pipeline(s) 140, particles 143 may be present in and dispersed throughout the liquid chemical 141. The particles 143 can include a portion of the particles 123 that are not filtered via the filtration system(s) prior to exiting the tank(s) of the factory supply system 130. The particles 143 can also include agglomerates of the particles 123 that form during storage in the tank(s) of the factory supply system 130. Other sources of the particles 143 can include one or more of pipeline debris, seal and/or gasket material, chemical precipitates, microbial contaminants, residual contaminants, and the like. The particles 143 being present in the liquid chemical 141 can result in process defects on the first semiconductor wafer 150, which reduce yield.

A particle monitoring or measuring system 160 that can determine concentration of particles 143 in the factory supply system 130 is described in accordance with various embodiments with reference to FIG. 1B. In response to the concentration of particles 143 exceeding a threshold value, various actions may be taken to mitigate the reduction in yield that is associated with exceeding the threshold value. For example, one or more supply tanks may be taken offline for maintenance, one or more flushing operations may be performed to remove particles 143 from transport lines, filtration systems, pumps, and the like. In another example, a system-wide preventative maintenance may be performed that removes particles 143 from the factory supply system 130.

FIG. 1B illustrates a detailed schematic view of the system 100 including the particle monitoring system 160, in accordance with some embodiments.

The system 100 includes the factory supply system or “liquid supply system” 130 and the particle monitoring system 160 in fluid communication therewith.

The liquid supply system 130 includes an intake assembly 131, a first storage tank or drum 132, a second storage tank or drum 133, a retrieval assembly 134, a supply assembly 135, a feedback assembly 136, and a valve manifold box (VMB) 137. The first and second storage tanks 132, 133 can be referred to collectively as the storage tanks 132, 133.

The intake assembly 131 is operable to receive the liquid chemical 121 from the truck 110 via a transport line 1311. The intake assembly 131 is further operable to output the liquid chemical 121 to the first storage tank 132, the second storage tank 133, or both. The intake assembly 131 is connected to the first storage tank 132 via a transport line 1312. The intake assembly 131 is connected to the second storage tank 133 via a transport line 1313. In some embodiments, the intake assembly 131 includes one or more valves that are coupled to the transport lines 1311, 1312, 1313 to control flow of the liquid chemical 121 into and out of the intake assembly 131 via the transport lines 1311, 1312, 1313. To supply the liquid chemical 121 to the first and second storage tanks 132, 133, the intake assembly 131 can include one or more pumps, one of which is depicted in FIG. 1B as a pump 131G. In some embodiments, the pump 131G includes a gas pressure pump, a pneumatic pump, a mechanical pump, or the like. The gas pressure pump can include one or more of a gas supply, an inlet, and the like, that generate a positive pressure differential that enables the liquid chemical 121 to be outputted from the intake assembly 131 without significant fluctuation in a flow rate thereof. The gas pressure pump can control pressure of a gas, such as N₂, He, Ar, CO₂, or the like that is supplied and held in the intake assembly 131. The mechanical pump can be or include one or more of piston pumps, plunger pumps, diaphragm pumps, gear pumps, lobe pumps, screw pumps, vane pumps, peristaltic pumps, centrifugal pumps, axial flow pumps, vacuum pumps, sump pumps, hydraulic pumps, and the like. In embodiments in which the pump 131G is the mechanical pump, the pump 131G is operable to generate variable pressure. As such, the pump 131G, which may include reciprocating or rotary mechanisms, produces pressure pulses in the flow of the liquid chemical 121. This can cause fluctuations in flow rate and potential vibrations.

The intake assembly 131 is in fluid communication with the particle monitoring system 160 via a transport line 1314. The particle monitoring system 160 is operable to sample the liquid chemical 121 at the intake assembly 131 via the transport line 1314. When sampling the liquid chemical 121 at the intake assembly 131, fluctuations in the flow rate and vibrations in the liquid chemical 121 being sampled can result in inaccuracy in measurement of particles 123 therein by a liquid particle counter (LPC) 170 of the particle monitoring system 160. In some embodiments, the particle monitoring system 160 includes a buffer tank 164 that has a gas pressure pump that is beneficial to remove fluctuations and vibrations from the liquid chemical 121 entering the LPC 170. Removal of fluctuations and vibrations from the liquid chemical 121 entering the LPC 170 improves control of trajectory of movement of the particles 123, which is beneficial to increase accuracy of particle measurement.

In some embodiments, the intake assembly 131 includes a filter or filtration system. The intake assembly 131 can receive liquid chemical 121 from the first storage tank 132, the second storage tank 133, or both. Then, the filter or filtration assembly thereof can remove particles from the liquid chemical 121 before supplying the liquid chemical 121 after filtering to the first storage tank 132, the second storage tank 133, or both.

The retrieval assembly 134 and the supply assembly 135 operate to supply or deliver the liquid chemical 121 to one or more semiconductor processing tools 138, such as an etching tool, a cleaning tool, or the like. The retrieval assembly 134 is in fluid communication with the first and second storage tanks 132, 133 to draw and/or receive the liquid chemical 121 from the first and second storage tanks 132, 133. In some embodiments, the retrieval assembly 134 includes a tank therein, in which the liquid chemical 121 can be stored temporarily or buffered prior to transport to the supply assembly 135. The retrieval assembly 134 is in fluid communication with the supply assembly 135. In some embodiments, the retrieval assembly 134 includes one or more pumps, a pump 134P of which is depicted in FIG. 1B. The pump 134P is a mechanical pump, such as one of the mechanical pumps described previously with reference to the pump 131G, in some embodiments. The pump 134P is operable to pump the liquid chemical 121 out of the retrieval assembly 134 to the supply assembly 135 via a transport line 1341. The retrieval assembly 134 is in fluid communication with the particle monitoring system 160 via a transport line 1342.

The supply assembly 135 is operable to supply the liquid chemical 121 to one or more tools. The supply assembly 135 is in fluid communication with the VMB 137, the retrieval assembly 134 and the particle monitoring system 160. In some embodiments, the supply assembly 135 includes a tank therein, in which the liquid chemical 121 can be stored temporarily or buffered prior to transport to the VMB 137. The supply assembly 135 is in fluid communication with the VMB 137. In some embodiments, the supply assembly 135 includes one or more pumps, a pump 135G of which is depicted in FIG. 1B. The pump 135G is a gas pressure pump, such as similar to the gas pressure pump described previously with reference to the pump 131G, in some embodiments. The pump 135G is operable to pump the liquid chemical 121 out of the supply assembly 135 to the VMB 137 via a transport line 1351. The supply assembly 135 is in fluid communication with the particle monitoring system 160 via a transport line 1352.

The feedback assembly 136 is operable to receive the liquid chemical 121 from the first and/or second storage tank 132, 133, filter the received liquid chemical 121 and output the filtered liquid chemical 121 back to the first and/or second storage tank 132, 133. The feedback assembly 136 is in fluid communication with the first and/or second storage tank 132, 133 and with the particle monitoring system 160. For example, the feedback assembly 136 is in fluid communication with the first storage tank 132 to receive the liquid chemical 121 from the first storage tank 132, and is in fluid communication with the first storage tank 132 to output the liquid chemical 121 to the first storage tank 132. In some embodiments, the feedback assembly 136 includes one or more filters that are operable to remove particles from the liquid chemical 121 received by the feedback assembly 136 from the first and/or second storage tank 132, 133. The feedback assembly 136 includes one or more pumps, a pump 136P of which is operable to output the liquid chemical 121 to the first and/or second storage tank 132, 133. The pump 136P is a mechanical pump, such as one of the mechanical pumps described previously with reference to the pump 131G, in some embodiments. The feedback assembly 136 is in fluid communication with the particle monitoring system 160 via a transport line 1362.

The particle monitoring system 160 is operable to sample and measure particles in the liquid chemical 121 at one or more of the intake assembly 131, the retrieval assembly 134, the supply assembly 135 and the feedback assembly 136. The particle monitoring system 160 includes a VMB 162, a buffer tank 164 and an LPC 170.

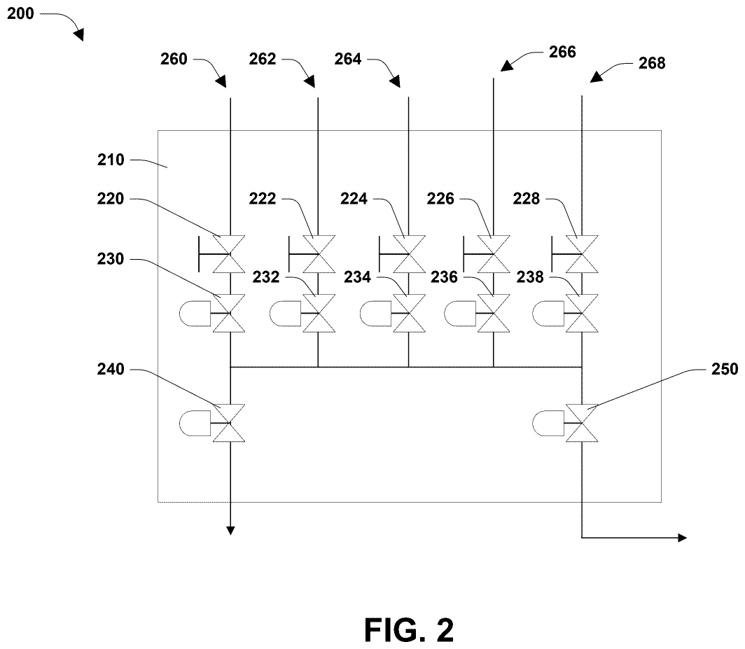

The VMB 162 receives the liquid chemical 121 from the transport lines 1314, 1342, 1352, 1362 and outputs the liquid chemical 121 from one of the transport lines 1314, 1342, 1352, 1362 to the buffer tank 164. The VMB 162 is in fluid communication with the buffer tank 164. A liquid selection apparatus 200 that is an embodiment of the VMB 162 is described in detail with reference to FIG. 2. The VMB 162 is operable to direct samples of the liquid chemical 121 from multiple points in the factory supply system 130 to the LPC 170 via the buffer tank 164, which can be beneficial to remove variations among the multiple points. For example, in operation, the VMB 162 can switch between different positions in the system 100, such as the intake assembly 131, the first storage tank 132, the second storage tank 133, the retrieval assembly 134, the supply assembly 135, the feedback assembly 136 or the like, as a source for sampling the liquid chemical 121, which is beneficial for one-stop detection and assessment of abnormality levels in the liquid chemical 121. Use of a single LPC 170 to perform measurement can be beneficial to increase uniformity of measurement conditions across all points sampled by the VMB 162.

The buffer tank 164 is a container or vessel designed to store temporarily the liquid chemical 121 sampled from the factory supply system 130, and to supply the liquid chemical 121 to the LPC 170. The liquid chemicals 121 can be highly pure and sensitive to contaminants, such that material of the buffer tank 164 and construction thereof are selected to maintain integrity of the liquid chemical 121. In some embodiments, the buffer tank 164 is constructed from stainless steel, glass or other suitable inert material(s) that are beneficial to reduce chemical contamination. The buffer tank 164 may be built with selected considerations for chemical compatibility, pressure, and temperature ratings associated with storage of the liquid chemical 121. The buffer tank 164 may include one or more of filters, ion exchange resins, or other purification devices that are beneficial to maintain chemical purity. In some embodiments, the buffer tank 164 has an agitation system that can reduce sedimentation or chemical stratification. In some embodiments, the buffer tank 164 includes a heating and/or cooling system that is beneficial to storing the liquid chemical 121 at a selected temperature. The buffer tank 164 can include one or more sensors to monitor liquid levels of the liquid chemical 121 in the buffer tank 164, which can be beneficial to reduce occurrence of overflow or underflow. Other components included in the buffer tank 164 can include shutoff valves, pressure relief valves and other safety devices.

The buffer tank 164 is beneficial to reduce presence of bubbles and pressure pulses in the liquid chemical 121 delivered to the LPC 170. The buffer tank 164 includes a gas pressure pump that can push the liquid chemical 121 out of the buffer tank 164 with very low disturbance or turbulence introduced thereto.

The LPC 170 is in fluid communication with the buffer tank 164 for receiving the liquid chemical 121 from the buffer tank 164. In some embodiments, the LPC 170 is operable to detect and measure small particles suspended in the liquid chemical 121. The LPC 170 is beneficial for semiconductor manufacturing, where even the tiniest contaminants can reduce yield.

In operation of the LPC 170, a liquid sample of the liquid chemical 121 is introduced into the LPC 170 through a controlled flow system, which can include the buffer tank 164 and the VMB 162. Flow rate of the liquid chemical 121 into the LPC 170 can be managed precisely to improve uniformity and accuracy of measurements. In some embodiments, a laser of the LPC 170 is used as a light source. The laser beam of the laser is directed through the liquid sample of the liquid chemical 121 as it flows through a detection chamber. When particles within the liquid sample pass through the laser beam, the particles scatter light. The amount and angle of the scattered light are associated with the size and nature of the particles. High-sensitivity photodetectors are placed around the detection chamber to capture the scattered light. The photodetectors are highly sensitive and capable of detecting even very faint signals caused by the small particles. The scattered light signals are converted into electrical signals. In some embodiments, one or more signal processing algorithms is used to distinguish real particle signals from noise, increasing accuracy of counting and sizing of the particles. The LPC 170 may be calibrated to associate intensity of the scattered light with particle size. This allows the LPC 170 to determine the size of each detected particle. The LPC 170 counts the number of particles detected within selected size ranges, which may occur in real-time. The number of particles may be recorded as data, which is beneficial for understanding contamination levels in the liquid sample. The LPC 170 can have stored therein software or processor-executable instructions for storing, managing, and analyzing the collected data. The instruction can include instructions for generating reports, monitoring trends over time, and setting alarms for when particle counts exceed selected thresholds. In some embodiments, the LPC 170 is operable to perform real-time monitoring of the particle count in each liquid sample, providing immediate feedback on particle contamination levels in the liquid chemical 121.

FIG. 2 illustrates a detailed schematic view of a liquid selection apparatus 200 of the system 100, in accordance with some embodiments. The liquid selection apparatus 200 is a variable manifold box or “VMB,” in accordance with some embodiments, and can be referred to as “the VMB 200” throughout the description. The VMB 200 is an embodiment of the VMB 162 of FIG. 1B and can be included in the system 100 described with reference to FIGS. 1A and 1B.

The VMB 200 includes a housing 210. Inside the housing 210, the VMB 200 includes one or more first valves 220, 222, 224, 226, 228, one or more corresponding second valves 230, 232, 234, 236, 238, a drain valve 240 and a supply valve or “sample valve” 250. Each of the first valves 220, 222, 224, 226, 228 is in fluid communication with a corresponding sample source of one or more sample sources 260, 262, 264, 266, 268. Each of the first valves 220, 222, 224, 226, 228 is in fluid communication with a corresponding one of the second valves 230, 232, 234, 236, 238. Each of the second valves 230, 232, 234, 236, 238 is in fluid communication with the drain valve 240 and the supply valve 250. In some embodiments, each of the first valves 220, 222, 224, 226, 228 is substantially the same in structure and composition as all others of the first valves 220, 222, 224, 226, 228. In some embodiments, each of the second valves 230, 232, 234, 236, 238 is substantially the same in structure and composition as all others of the second valves 230, 232, 234, 236, 238. This is beneficial to improve uniformity of collection of samples of the liquid chemicals 121 from sample sources 260, 262, 264, 266, 268 in fluid communication therewith.

The first valve 220 is in fluid communication with a sample source 260, which may be the intake assembly 131 and/or the transport line 1314. The first valve 222 is in fluid communication with a sample source 262, which may be the retrieval assembly 134 and/or the transport line 1342. The first valve 224 is in fluid communication with a sample source 264, which may be feedback assembly 136 and/or the transport line 1362. The first valve 226 is in fluid communication with a sample source 266, which may be the supply assembly 135 and/or the transport line 1352. The first valve 228 is in fluid communication with a sample source 268, which may be another supply assembly similar to the supply assembly 135.

The supply assembly 135 can be a “frontend” supply assembly 135 and the another supply assembly can be a “backend” supply assembly, in accordance with some embodiments. In some embodiments, the frontend supply assembly 135 supplies the liquid chemical 121 to “frontend” tools, which can include one or more of photolithography machines, etchers, chemical vapor deposition (CVD) tools, ion implanters, oxidation furnaces, chemical mechanical planarization (CMP) tools, and the like. In some embodiments, the backend supply assembly supplies the liquid chemical 121 to “backend” tools, which can include one or more of dicing saws, wire bonding machines, flip-chip bonders, encapsulation tools, testing equipment and the like. The first valve 228 can be in fluid communication with the backend supply assembly via one or more suitable transport lines similar to the transport line 1352.

In some embodiments, each of the first valves 220, 222, 224, 226, 228 is a manual valve, which may be hand-operated. Briefly, the manual valve may be operated manually by turning a handwheel, lever, or knob, for example, by a human operator who directly controls the manual valve's opening and closing. As such, the manual valve may benefit from human effort and presence for operation. The manual valve may be beneficial to provide infrequent and/or precise manual control. The manual valve can include a rotating or sliding mechanism controlled by the human operator.

In some embodiments, each of the second valves 230, 232, 234, 236, 238, the drain valve 240 and the supply valve 250 is a pneumatic valve, which may be a diaphragm valve. The pneumatic valve can be operated by compressed air to move a diaphragm that opens or closes the valve. The diaphragm separates a flow media (e.g., the liquid chemical 121) from an actuator. In some embodiments, the pneumatic valve is a component of an automated system, and can be controlled remotely via air pressure signals, which can be or include electronic signals generated by a controller circuit. The pneumatic valve has benefits of precise and consistent operation. In some embodiments, the pneumatic valve can include a diaphragm, actuator, and other pneumatic components.

In operation, the first valves 220, 222, 224, 226, 228 may be open to allow flow of the liquid chemical 121 from the sample sources 260, 262, 264, 266, 268. In some embodiments, one or more of the first valves 220, 222, 224, 226, 228 is closed, for example, when a corresponding sample source(s) of the sample sources 260, 262, 264, 266, 268 is offline or no sampling therefrom is to be performed.

Then, one of the second valves 230, 232, 234, 236, 238 is opened to allow the liquid chemical 121 from the corresponding sample source of the sample sources 260, 262, 264, 266, 268 to flow to the sample valve 250. Others of the second valves 230, 232, 234, 236, 238 are closed to prevent flow to the sample valve 250 from the others of the sample sources 260, 262, 264, 266, 268.

Then, the sample valve 250 may be opened to allow the liquid chemical 121 from the selected sample source to flow to the LPC 170.

Then, following measurement by the LPC 170, the sample valve 250 and the selected second valve of the second valves 230, 232, 234, 236, 238 may be closed and the drain valve 240 may be opened to drain the liquid chemical 121 that is present between the second valves 230, 232, 234, 236, 238 and the sample and drain valves 250, 240. The liquid chemical 121 drains out of the VMB 200, for example, to a waste collection system or a feedback system that can return the liquid chemical 121 to the first and/or second storage tank 132, 133.

Following removal of the liquid chemical 121 via the drain valve 240, a different one of the second valves 230, 232, 234, 236, 238 can be opened and others of the second valves 230, 232, 234, 236, 238 can be closed to sample the liquid chemical 121 from a corresponding sample source of the sample sources 260, 262, 264, 266, 268. Via similar operations to those just described, the liquid chemical 121 can be measured by the LPC 170 and then excess liquid chemical 121 can be drained following the measurement by the LPC 170.

Use of the VMB 200 has benefits of improving uniformity of measurements of particles in the liquid chemical 121 across the sample sources 260, 262, 264, 266, 268. One reason for this is that the measurements are performed by the same LPC 170 for all samples and that the samples are all transported through the same sample valve 250 and through similar first valves 220, 222, 224, 226, 228 and similar second valves 230, 232, 234, 236, 238.

It should be understood that, while not individually labeled in FIG. 2, the sample sources 260, 262, 264, 266, 268, the first valves 220, 222, 224, 226, 228, the second valves 230, 232, 234, 236, 238, the sample valve 250 and the drain valve 240 are in fluid communication with each other via one or more transport lines, which are depicted as solid lines.

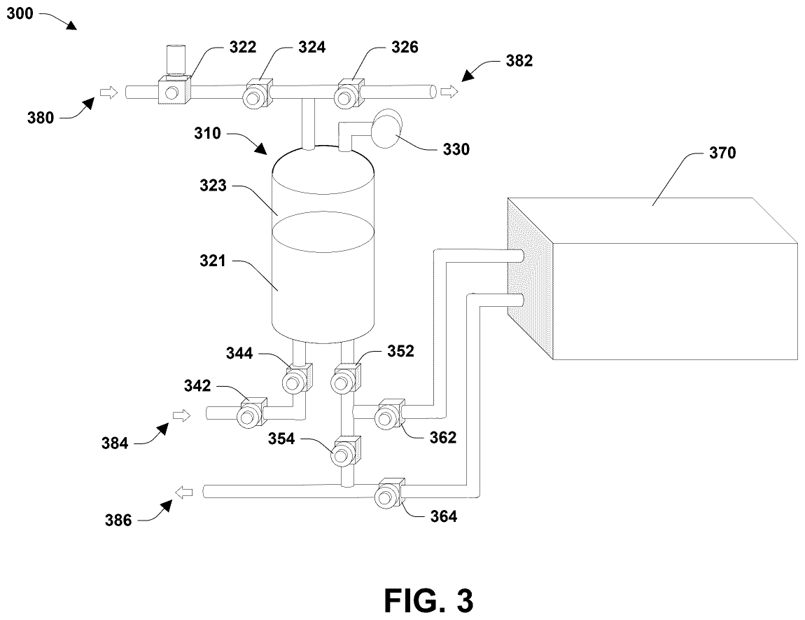

FIG. 3 illustrates a schematic view of a measurement system 300 having a buffer tank 310, in accordance with some embodiments.

In FIG. 3, the measurement system 300 includes the buffer tank 310, a flow meter 322, pressure supply valves 324, 326, a pressure measurement assembly 330, sampling valves 342, 344, measurement valves 352, 362, drain valves 354, 364 and an LPC 370. The LPC 370 is similar in most respects to the LPC 170 described with reference to FIGS. 1A and 1B.

The buffer tank 310 is operable to hold and contain a liquid chemical 321, which is similar in most respects to the liquid chemical 121 described with reference to FIGS. 1A-2. In some embodiments, the buffer tank 310 is or includes containing walls that are a per- or polyfluoroalkyl (PFA) material or another suitable material that is highly resistant to a wide range of acids, alkalis, salts and other corrosive chemicals while also having a non-reactive surface that is inert to most chemicals.

In some embodiments, the containing walls of the buffer tank 310 can be or include polyvinyl chloride (PVC), polypropylene (PP), polyethylene (PE), polyvinylidene fluoride (PVDF), polytetrafluoroethylene (PTFE), fiberglass reinforced plastic (FRP), high-density polyethylene (HDPE), chlorinated polyvinyl chloride (CPVC), or the like.

A flow meter 322 is in fluid (or gas) communication with a gas supply 380. In some embodiments, the gas supply 380 is operable to supply pressurized gas, which is an inert gas, such as N₂, He, Ar, CO₂ gas, or the like. The flow meter 322 is in fluid (or gas) communication with the pressure supply valve 324. In some embodiments, the flow meter 322 is or includes one or more of a thermal mass flow meter, Coriolis mass flow meter, variable area flow meter (or “rotameter”), mass flow controller (MFC), differential pressure flow meter, ultrasonic flow meter, turbine flow meter, pressure-based flow meter or the like.

The pressure supply valve 324 is in fluid (or gas) communication with the buffer tank 310. In operation, the pressure supply valve 324 can be opened to allow flow of the pressurized gas to the buffer tank 310. Pressurized gas 323 supplied via the pressure supply valve 324 is present in the buffer tank 310. The pressurized gas 323 operates to press out the liquid chemical 321 toward the LPC 370 without substantially generating bubbles therein, which is beneficial to improve measurement accuracy and stability of particles in the liquid chemical 321 by the LPC 370. The pressure supply valve 324 can be electronically adjustable and controllable by a controller, such as a microcontroller unit (MCU) or the like. Adjustment of the pressure supply valve 324 can be in response to a flow value measured by the flow meter 322, a pressure value measured by a pressure measurement assembly 330, or both.

The pressure supply valves 324, 326 are in fluid communication with an upper portion of the buffer tank 310. The upper portion can be considered a portion of the buffer tank 310 at which the pressurized gas 323 collects, rests, and is generally present. A lower portion of the buffer tank 310 can be considered a portion of the buffer tank 310 at which the liquid chemical 321 collects, rests, and is present. Having the pressurized gas 323 enter the buffer tank 310 at the upper portion (or a “first side”) of the buffer tank 310 can reduce generation of perturbances in the liquid chemical 321. Similarly, having the liquid chemical 321 enter the buffer tank 310 at the lower portion (or a “second side” opposite the first side) of the buffer tank 310 can reduced generation of perturbances in the liquid chemical 321. Reduced perturbation can result in reduced occurrence of bubbles in the liquid chemical 321 supplied to the LPC 370, which can improve uniformity and accuracy of measurement of particles in the liquid chemical 321 by the LPC 370.

The pressure supply valve 326 may be the same type of valve as the pressure supply valve 324. In operation, the pressure supply valve 326 can be opened to allow exhaust of the pressurized gas 323 from the buffer tank 310. For example, the pressure measurement assembly 330 in fluid (or gas) communication with the buffer tank 310 can determine pressure of the pressurized gas 323 in the buffer tank 310 while the pressure supply valve 326 is closed. In response to the pressure being above a selected value as measured by the pressure measurement assembly 330, the pressure supply valve 326 is opened and the pressure supply valve 324 is closed to exhaust some of the pressurized gas 323 from the buffer tank 310. The exhausting may be to an exhaust system 382 in fluid (or gas) communication with the buffer tank 310 via the pressure supply valve 326. Following exhausting of the pressurized gas 323 from the buffer tank 310, pressure of the pressurized gas 323 in the buffer tank 310 may decrease. In response to the pressure being below the selected value as measured by the pressure measurement assembly 330, the pressure supply valve 326 may be closed to stop exhausting of the pressurized gas 323 from the buffer tank 310.

The pressure measurement assembly or apparatus 330 is in fluid or gas communication with the buffer tank 310 and is operable to measure pressure of the buffer tank 310. The pressure measurement assembly 330 can be or include one or more of capacitance manometers, Pirani gauges, ionization gauges, Baratron gauges, piezoelectric pressure sensors, thermocouple gauges, quartz crystal microbalance (QCM) sensors, differential pressure transducers, combinations thereof or the like.

The buffer tank 310 is in fluid communication with a sampling source 384 via the sampling valves 342, 344. The sampling source 384 may be the VMB 200 described with reference to FIG. 2. In some embodiments, the sampling valve 342 is in fluid communication with the supply valve 250 of the VMB 200. In some embodiments, the sampling valve 342, the sampling valve 344, or both, is the supply valve 250 of the VMB 200.

In operation, the sampling valves 342, 344 are opened to allow flow of the liquid chemical 321 from the sampling source 384 (e.g., the VMB 200) into the buffer tank 310. In some embodiments, prior to opening the sampling valves 342, 344, liquid chemical 321 remaining in the buffer tank 310 from a prior sampling and measurement operation is drained, such that the buffer tank 310 is substantially empty prior to the sampling valves 342, 344 being opened. Prior to measurement of the liquid chemical 321 introduced into the buffer tank 310 via the opened sampling valves 342, 344, the sampling valves 342, 344 may be closed to stop flow of the liquid chemical 321 into the buffer tank 310. This can be beneficial to reduce perturbation of the liquid chemical 321 in the buffer tank 310 during measurement of particles thereof by the LPC 370. In some embodiments, a selected volume of the liquid chemical 321 can be supplied to, and stored in, the buffer tank 310 prior to beginning measurement of particles thereof.

The measurement system 300 includes the measurement valves 352, 362. The measurement valves 352, 362 are in fluid communication with the buffer tank 310 and the LPC 370. In a measurement operation, the measurement valves 352, 362 are operable to open to allow flow of the liquid chemical 321 from the buffer tank 310 to the LPC 370. During the measurement operation, the measurement valves 352, 362 and the drain valve 364 are open. While the measurement and drain valves 352, 362, 364 are open, the liquid chemical 321 flows out of the buffer tank 310, into the LPC 370, out of the LPC 370 and out of the measurement system 300 to a drain system 386. Flow rate of the liquid chemical 321 into the LPC 370 can be controlled to be a selected flow value, which in a range of about 5 cc/minute to about 50 cc/minute, such as about 10 cc/min, about 35 cc/min, or another suitable flow rate value in the range. In FIG. 3, a single LPC 370 is depicted as being included in the measurement system 300. In some embodiments, additional LPCs are included in the measurement system 300. For example, the measurement system 300 can include a first LPC (e.g., the LPC 370) and a second LPC. The first LPC can operate using a first flow value, such as about 10 cc/min, and the second LPC can operation using a second flow value different than the first flow value, such as about 35 cc/min. The first LPC can measure a first particle count in a first sample associated with a first apparatus (e.g., one of the intake assembly 131, the retrieval assembly 134, the supply assembly 135 or the feedback assembly 136), and the second LPC can measure a second particle count in a second sample associated with a second apparatus (e.g., another of the intake assembly 131, the retrieval assembly 134, the supply assembly 135 or the feedback assembly 136).

In some embodiments, the measurement system 300 includes a flow meter that is positioned between the buffer tank 310 and the LPC 370. For example, the flow meter may be positioned between the buffer tank 310 and the measurement valve 352. In another example, the flow meter may be positioned between the measurement valve 352 and the measurement valve 362. In yet another example, the flow meter may be positioned between the measurement valve 362 and the LPC 370. In some embodiments, the flow meter is positioned inside the LPC 370. In some embodiments, the flow meter is positioned between the LPC 370 and the drain valve 364.

Prior to performing a measurement operation, to drain the liquid chemical 321 from the buffer tank 310, the measurement valve 352 and the drain valve 354 may be opened, which allows the liquid chemical 321 to drain out of the buffer tank 310 toward the drain system 386. This can be referred to as a drain operation. The drain operation may be performed between each two successive sampling and measurement operations. For example, a first sampling and measurement operation may be performed to sample and measure the liquid chemical 321 from one of the intake assembly 131, the retrieval assembly 134, the supply assembly 135, or the feedback assembly 136. Then, a drain operation may be performed to remove the liquid chemical 321 used in the first sampling and measurement operation. Then, a second sampling and measurement operation may be performed to sample and measure the liquid chemical 321 from another of the intake assembly 131, the retrieval assembly 134, the supply assembly 135, or the feedback assembly 136.

Using the operations described above with reference to FIG. 3, the measurement system 300 can obtain a first particle count associated with a first sample of a first apparatus and a second particle count associated with a second sample of a second apparatus. As one example, the first particle count can be associated with the first sample taken from a first position prior to a filter, and the second particle count can be associated with the second sample taken from a second position following the filter. In response to a difference between the first particle count and the second particle count being less than a threshold value, the filter may be scheduled for preventative maintenance, repair, or replacement. The difference being less than the threshold value can indicate that the filter is removing an insufficient number of particles from the liquid chemical passing therethrough.

In another example, the first particle count can be associated with the first sample taken from a first position at an inlet or outlet of a first storage tank (e.g., the first storage tank 132), and the second particle count can be associated with the second sample taken from a second position at an inlet or outlet of a second storage tank (e.g., the second storage tank 133). Then, the first and second particle counts can be compared with each other to determine a difference in cleanliness between the first storage tank and the second storage tank. In response to the first or second particle count exceeding a threshold value, the first or second storage tank may be scheduled for preventative maintenance, repair, or replacement, which can include flushing, cleaning, or another suitable action.

In another example, the first particle count can be associated with the first sample taken from a first position at an outlet of a first pump (e.g., one of the pumps 131G, 134P, 136P, 135G), and the second particle count can be associated with the second sample taken from a second position at an outlet of a second pump (e.g., another of the pumps 131G, 134P, 136P, 135G). Then, the first and second particle counts can be compared with each other to determine a difference in cleanliness between the first pump and the second pump. In response to the first or second particle count exceeding a threshold value, the first or second pump may be scheduled for preventative maintenance, repair, or replacement, which can include flushing, cleaning, or another suitable action.

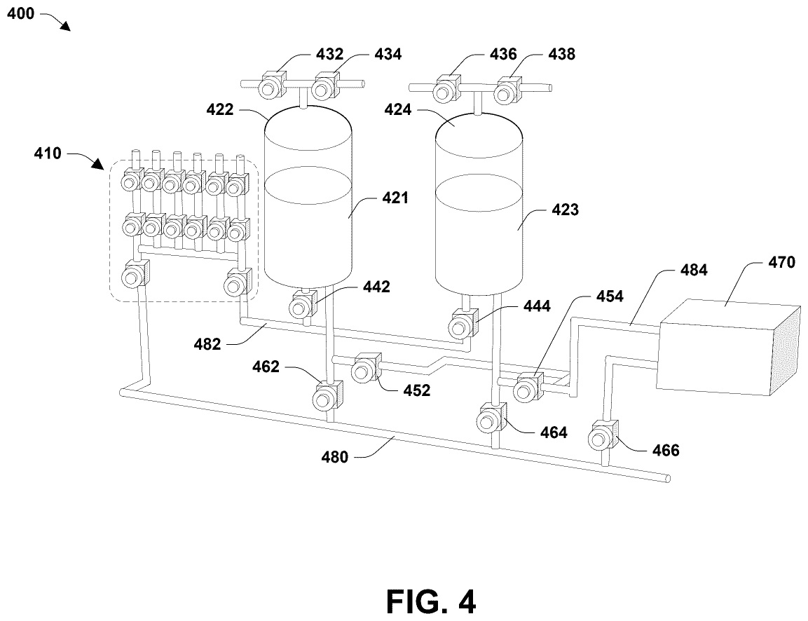

FIG. 4 illustrates a schematic view of a measurement system 400 and a liquid selection apparatus 410, in accordance with some embodiments. The measurement system 400 and the liquid selection apparatus 410 are similar in most respects to the measurement system 300 and the VMB 200, respectively.

In FIG. 4, the measurement system 400 includes a first buffer tank 422 and a second buffer tank 424, which are similar in most respects to the buffer tank 310. The first buffer tank 422 is in fluid communication with pressure supply valves 432, 434. The second buffer tank 424 is in fluid communication with pressure supply valves 436, 438. The pressure supply valves 432, 434, 436, 438 are similar in most respects to the pressure supply valves 324, 326 of FIG. 3.

The first buffer tank 422 is in fluid communication with a sampling valve 442, which is in fluid communication with the liquid selection apparatus 410 via a transport line 482. The second buffer tank 424 is in fluid communication with a sampling valve 444, which is in fluid communication with the liquid selection apparatus 410 via the transport line 482. The sampling valves 442, 444 are similar in most respects to the sampling valve 344 of FIG. 3.

The first buffer tank 422 is in fluid communication with a drain transport line 480 via a drain valve 462. The second buffer tank 424 is in fluid communication with the drain transport line 480 via a drain valve 464. The drain valves 462, 464 are similar in most respects to the drain valve 354 of FIG. 3.

The first buffer tank 422 is in fluid communication with an LPC 470 via a measurement valve 452 and a measurement transport line 484. The first second tank 424 is in fluid communication with the LPC 470 via a measurement valve 454 and the measurement transport line 484. The measurement valves 452, 454 are similar in most respects to the measurement valve 362 of FIG. 3.

The LPC 470 is in fluid communication with the drain transport line 480 via a drain valve 466, which is similar in most respects to the drain valve 364 of FIG. 3.

The measurement system 400 including the first and second buffer tanks 422, 424 can provide benefits. For example, the first buffer tank 422 can contain first liquid chemical 421 from a first apparatus of the intake assembly 131, the retrieval assembly 134, the supply assembly 135 and the feedback assembly 136, and the second buffer tank 424 can contain second liquid chemical 426 from a second apparatus of the intake assembly 131, the retrieval assembly 134, the supply assembly 135 and the feedback assembly 136. The first and second liquid chemicals 421, 423 (or “the liquid chemicals 421, 423”) are similar in most respects to the liquid chemical 121 and the liquid chemical 321 described with reference to FIGS. 1A and 3, respectively. Then, the first liquid chemical 421 can be measured by the LPC 470, followed by measuring the second chemical 423 by the LPC 470. In some embodiments, during measurement of the first liquid chemical 421 by the LPC 470, the second chemical 423 can be sampled and transported into the second buffer tank 424. This can improve uptime of the LPC 470.

Another benefit of including the first and second buffer tanks 422, 424 is ability to take one of the first and second buffer tanks 422, 424 offline (e.g., for preventative maintenance or repair) while continuing to operate the other of the first and second buffer tanks 422, 424 to measure the first or second liquid chemical 421, 423 via the LPC 470. This can improve uptime of the LPC 470.

Although two buffer tanks 422, 424 are described with reference to FIG. 4, additional buffer tanks can be included in the measurement system 400. For example, the measurement system 400 can include three buffer tanks, four buffer tanks, or more buffer tanks. Each of the buffer tanks can be in fluid communication with the LPC 470 and the liquid selection apparatus 410 to allow for input of liquid chemical into the respective buffer tank and output of the liquid chemical to the LPC 470 for measurement of particles therein.

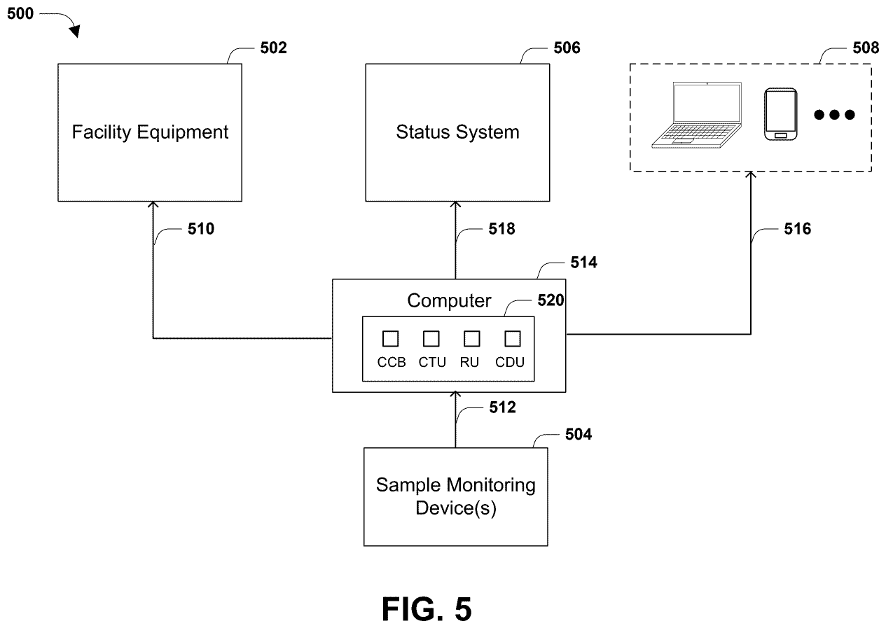

FIG. 5 illustrates a schematic view of a particle monitoring system 500, in accordance with some embodiments. The particle monitoring system 500 comprises at least one of a set of sample monitoring devices 504, facility equipment 502 of a facility, a computer 514, a status system 506, or one or more client devices 508. The set of sample monitoring devices 504 comprises sample monitoring devices distributed at various locations of the facility. The sample monitoring devices are used to determine measurements associated with devices and/or other equipment in the facility, such as the intake assembly 131, the retrieval assembly 134, the supply assembly 135, and the feedback assembly 136 described with reference to FIG. 1B.

In some embodiments, the set of sample monitoring devices 504 transmit a set of monitoring signals 512 to the computer 514. In some embodiments, each signal of the set of monitoring signals 512 is transmitted by a monitoring device (e.g., the LPC 370 or the LPC 470), of the set of sample monitoring devices 504, in a liquid chemical supply system of the facility.

In some embodiments, the set of monitoring signals 512 comprises a first monitoring signal from the LPC 370 or the LPC 470. In some embodiments, the LPC 370 and/or the LPC 470 comprises a wireless communication module that transmits the first monitoring signal to the computer 514 wirelessly. In some embodiments, the LPC 370 and/or the LPC 470 transmits the first monitoring signal to the computer 514 over a wired connection between the LPC 370 and/or the LPC 470 and the computer 514. In some embodiments, the first monitoring signal is indicative of the level of particles (e.g., particle count) associated with the liquid chemical 321, 421, 423 sampled by the measurement system 300 or the measurement system 400, respectively.

In some embodiments, the set of monitoring signals 512 comprises a second monitoring signal from the LPC 370 and/or the LPC 470. In some embodiments, the second monitoring signal is indicative of the level of particles (e.g., particle count) associated with the liquid chemical 321, 421, 423 sampled by the measurement system 300 or the measurement system 400, respectively. The first monitoring signal may be indicative of a first level of particles associated with a first apparatus of the intake assembly or “CCB” 131, the retrieval assembly or “CTU” 134, the supply assembly or “CDU” 135 and the feedback assembly or “RU” 136, and the second monitoring signal may be indicative of a second level of particles associated with a second apparatus of the intake assembly 131, the retrieval assembly 134, the supply assembly 135 and the feedback assembly 136.

In some embodiments, the computer 514 controls a display panel 520 comprising a set of status indicators associated with apparatuses (e.g., the CCB 131, CTU 134, CDU 135, and RU 136) of the liquid chemical supply system in the facility. In some embodiments, an indicator of the set of status indicators comprises a light, such as an indicator light, that indicates whether a corresponding apparatus is associated with a particle level, wherein the light being in a first state indicates that the corresponding apparatus is associated with the particle level exceeding a threshold value and/or the light being in a second state indicates that the corresponding apparatus is not associated with the particle level exceeding the threshold value. In some embodiments, the display panel 520 comprises a display configured to display an alert indicative of one or more detected particle monitoring statuses of one or more apparatuses. In some embodiments, the first state corresponds to a first color emitted by the light, such as red or other color, and the second state corresponds to a second color emitted by the light, such as green or other color. The set of status indicators comprises at least one of a first indicator “CCB” associated with a first apparatus (e.g., the CCB 131), a second indicator “CTU” associated with a second apparatus (e.g., the CTU 134), a third indicator “RU” associated with a third apparatus (e.g., the RU 136), a fourth indicator “CDU” associated with a fourth apparatus (e.g., the CDU 135), or other indicator.

In some embodiments, the computer 514 provides one or more first signals 510 to the facility equipment 502. In some embodiments, the one or more first signals 510 are used to control at least some of the facility equipment 502, such as one, some or all liquid chemical supply systems of the facility and/or other equipment of the facility. In some embodiments, the one or more first signals 510 are generated using a signal generator of the computer 514. The one or more first signals 510 can be indicative of particle level of liquid chemical in the liquid chemical supply system(s). In some embodiments, the computer 514 transmits the one or more first signals 510 to the facility equipment 502 wirelessly, such as using a wireless communication device of the computer 514. In some embodiments, the computer 514 transmits the one or more first signals 510 to the facility equipment 502 over a physical connection between the computer 514 and the facility equipment 502. In some embodiments, the computer 514 transmits the one or more first signals 510 to a controller that controls one or more valves of the liquid chemical supply system. For example, the controller may control one or more of the pressure supply valves 342, 432, 436 to adjust flow of the pressurized gas into the buffer tank(s) 310, 422, 424, which adjusts flow rate of the liquid chemical 321, 421, 423 out of the buffer tank(s) 310, 422, 424.

In some embodiments, the computer 514 transmits a second signal 518 to the status system 506. The second signal 518 is generated using the signal generator of the computer 514. In some embodiments, the second signal 518 is indicative of at least one of (i) the set of particle monitoring statuses, (ii) the list of apparatuses that are determined to have particle level exceeding a selected threshold value, or (iii) other information. In some embodiments, the computer 514 transmits the second signal 518 to the status system 506 wirelessly, such as using the wireless communication device of the computer 514. In some embodiments, the computer 514 transmits the second signal 518 to the status system 506 over a physical connection between the computer 514 and the status system 506. In some embodiments, the status system 506 triggers an alarm function based upon the second signal 518. In some embodiments, the status system 506 triggers the alarm function based upon the second signal 518 indicating that the apparatus is associated with a particle level exceeding the selected threshold value. In some embodiments, in response to triggering the alarm function, an alarm message is displayed via a display of the status system 506. The alarm message comprises at least one of an indication that the apparatus is associated with the particle level exceeding the selected threshold value, an indication of lead time to perform preventative maintenance, an indication comprising an instruction for the liquid chemical supply system to cease operating (until the particle level is sufficiently low, for example), or other indication. In some embodiments, an alarm sound is output via a speaker connected to the status system 506 in response to triggering the alarm function.

In some embodiments, the computer 514 transmits a third signal 516 to one or more client devices 508. The one or more client devices 508 comprise at least one of a phone, a smartphone, a mobile phone, a landline, a laptop, a desktop computer, hardware, or other type of client device. The third signal 516 is generated using the signal generator of the computer 514. In some embodiments, the third signal 516 is indicative of at least one of (i) the set of particle monitoring statuses, (ii) the list of apparatuses that are determined to be associated with the particle level that exceeds the selected threshold value, or (iii) other information. In some embodiments, the computer 514 transmits the third signal 516 to a client device of the one or more client devices 508 wirelessly, such as using the wireless communication device of the computer 514. In some embodiments, the computer 514 transmits the third signal 516 to a client device of the one or more client devices 508 over a physical connection between the computer 514 and the client device. In some embodiments, the third signal 516 comprises a message, such as at least one of an email, a text message, etc., transmitted in response to detecting one or more particle levels that exceed the selected threshold value. In some embodiments, in response to detecting a particle value exceeding the selected threshold value associated with an apparatus, a telephonic call is made to a client device, such as a landline or a mobile phone, of the one or more client devices 508, such as using a dialer of the computer 514.

In some embodiments, the set of monitoring signals 512 are used as feedback based upon which operation of the facility equipment 502 is controlled by the computer 514. In some embodiments, the computer 514 controls operation of the facility equipment 502 based upon measurements provided by the set of monitoring signals 512. In some embodiments, operation of the facility equipment 502 is controlled using the one or more first signals 510. In some embodiments, a signal of the one or more first signals 510 is indicative of one or more instructions.

In some embodiments, the system 100 of the facility equipment 502 at least one of ceases operation, enters a locked state, or performs another operation in response to receiving a signal (of the one or more first signals 510) indicating that the particle level exceeds the selected threshold value. In some embodiments, the one or more first signals 510 comprise a signal transmitted to a machine, such as the system 100. In some embodiments, the signal instructs the machine to engage the first storage tank 132 while the second storage tank 133 is undergoing preventative maintenance. In some embodiments, the signal allocates one or more resources (e.g., manpower, a robot, one or more tools, the replacement component, etc.) to the second storage tank 133 to be used for remedying the halt associated with the second storage tank 133.

In some embodiments, in response to determining that the second storage tank 133 is not associated with a halt, the second storage tank 133 is used to supply liquid chemical to the tool(s), so as to perform an etching process or other suitable process on the first semiconductor wafer 150. In some embodiments, in response to determining that the second storage tank 133 is associated with the halt, the computer 514 instructs the second storage tank 133 to not deliver the liquid chemical (until the halt is addressed, for example). During the system 100 not delivering the liquid chemical via the second storage tank 133, the system 100 may deliver the liquid chemical via another storage tank, such as the first storage tank 132.

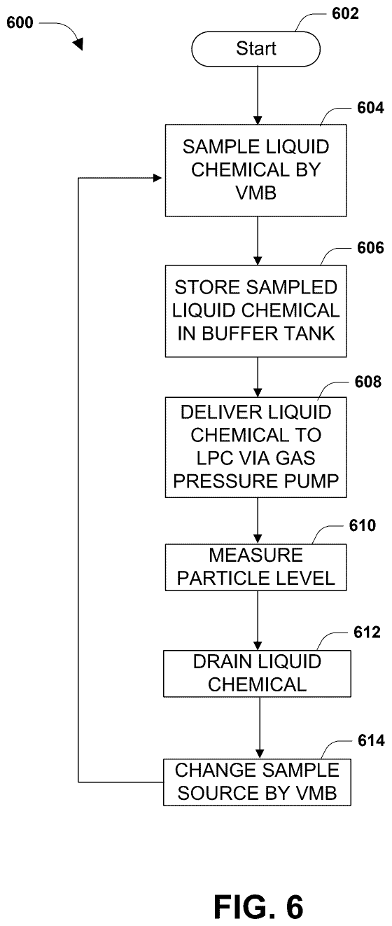

FIG. 6 is a flow diagram illustrating a method 600 of operating a liquid chemical supply system, in accordance with some embodiments.

The method 600 is illustrated in FIG. 6 in accordance with some embodiments. The method begins at 602. At 604, the method 600 includes sampling liquid chemical of the liquid chemical supply system via a VMB. At 606, the method 600 includes storing the sampled liquid chemical in a buffer tank. At 608, the method 600 includes delivering the sampled liquid chemical to an LPC via a gas pressure pump in fluid communication with the buffer tank. At 610, the method 600 includes measuring a particle level of the sampled liquid chemical via the LPC. At 612, the method 600 includes draining the liquid chemical from the LPC, the buffer tank, the VMB and transport lines connected therebetween. At 614, the method 600 includes changing a sample source by the VMB. Following 614, the method 600 returns to 604 to sample the liquid chemical from the sample source.

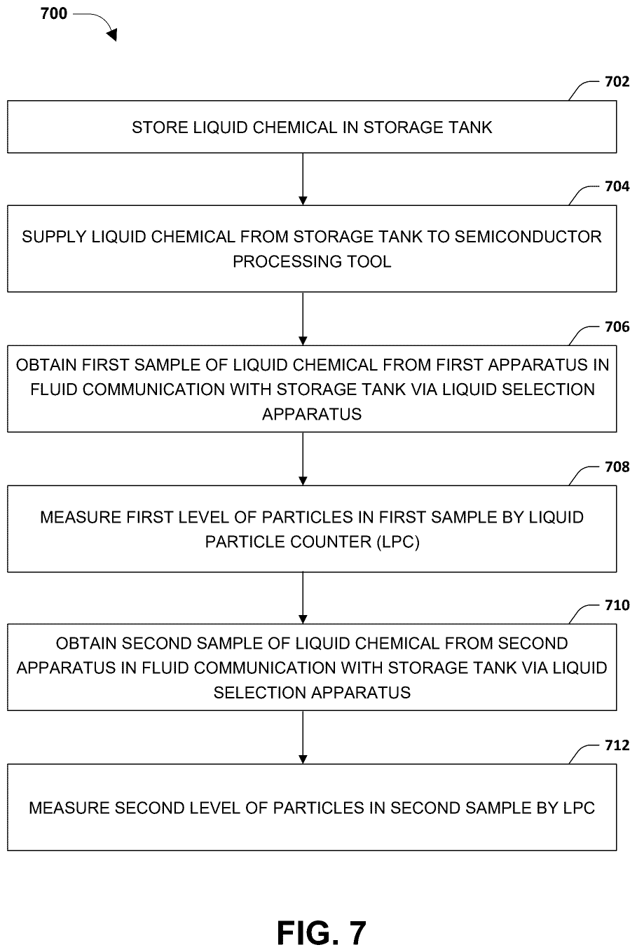

FIG. 7 is a flow diagram illustrating a method 700, in accordance with some embodiments.

The method 700 is illustrated in FIG. 7 in accordance with some embodiments. At 702, the method 700 includes storing a liquid chemical in a storage tank. At 704, the method 700 includes supplying the liquid chemical from the storage tank to a semiconductor processing tool. At 706, the method 700 includes obtaining a first sample of the liquid chemical from a first apparatus in fluid communication with the storage tank via a liquid selection apparatus. At 708, the method 700 includes measuring a first level of particles in the first sample by a liquid particle counter (LPC). At 710, the method 700 includes, after obtaining the first sample, obtaining a second sample of the liquid chemical from a second apparatus in fluid communication with the storage tank via the liquid selection apparatus, the second apparatus being different than the first apparatus. At 712, the method 700 includes measuring a second level of particles in the second sample by the LPC.

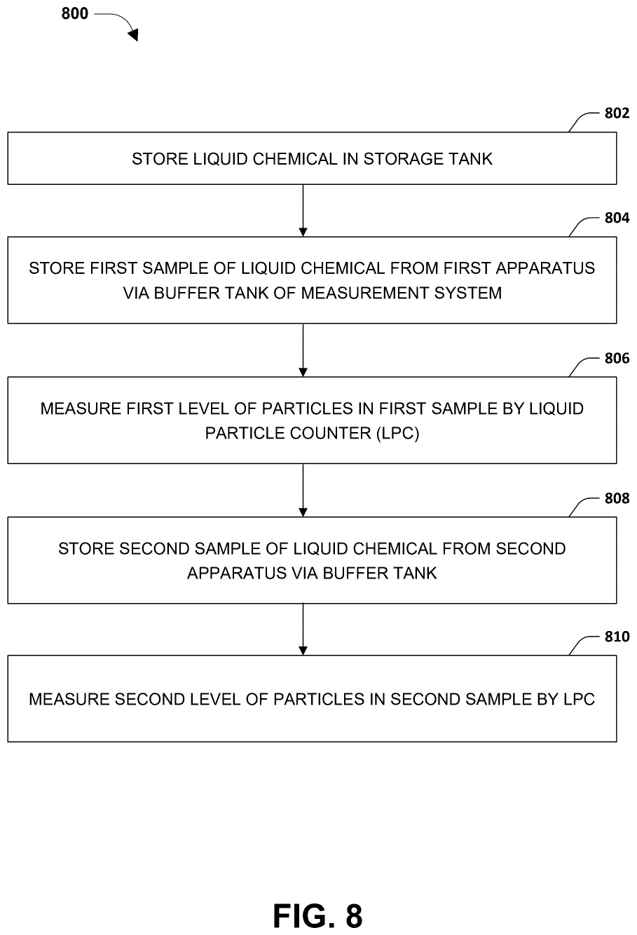

FIG. 8 is a flow diagram illustrating a method 800, in accordance with some embodiments.

A method 800 is illustrated in FIG. 8 in accordance with some embodiments. At 802, the method 800 includes storing a liquid chemical in a storage tank. At 804, the method 800 includes storing a first sample of the liquid chemical from a first apparatus in fluid communication with the storage tank via a buffer tank of a measurement system in fluid communication with the first apparatus. At 806, the method 800 includes measuring a first level of particles in the first sample by a liquid particle counter (LPC). At 808, the method 800 includes, after storing the first sample, storing a second sample of the liquid chemical from a second apparatus in fluid communication with the storage tank via the buffer tank, the second apparatus being different than the first apparatus. At 810, the method 800 includes measuring a second level of particles in the second sample by the LPC.

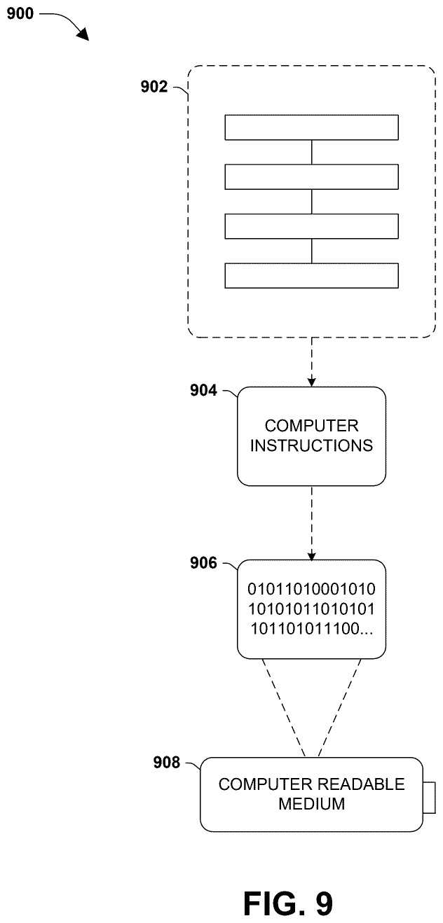

FIG. 9 illustrates an example computer-readable medium wherein processor-executable instructions configured to embody one or more of the provisions set forth herein may be comprised, according to some embodiments.

One or more embodiments involve a computer-readable medium comprising processor-executable instructions configured to implement one or more of the techniques presented herein. An exemplary computer-readable medium is illustrated in FIG. 9, wherein the embodiment 900 comprises a computer-readable medium 908 (e.g., a CD-R, DVD-R, flash drive, a platter of a hard disk drive, etc.), on which is encoded computer-readable data 906. This computer-readable data 906 in turn comprises a set of processor-executable computer instructions 904 configured to implement one or more of the principles set forth herein when executed by a processor. In some embodiments 900, the processor-executable computer instructions 904 are configured to implement a method 902, such as at least some of the aforementioned method(s) when executed by a processor. In some embodiments, the processor-executable computer instructions 904 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a method is provided. The method includes: storing a liquid chemical in a storage tank; supplying the liquid chemical from the storage tank to a semiconductor processing tool; obtaining a first sample of the liquid chemical from a first apparatus in fluid communication with the storage tank via a liquid selection apparatus; measuring a first level of particles in the first sample by a liquid particle counter (LPC); after obtaining the first sample, obtaining a second sample of the liquid chemical from a second apparatus in fluid communication with the storage tank via the liquid selection apparatus, the second apparatus being different than the first apparatus; and measuring a second level of particles in the second sample by the LPC.

In some embodiments, a method is provided. The method includes: storing a liquid chemical in a storage tank; storing a first sample of the liquid chemical from a first apparatus in fluid communication with the storage tank via a buffer tank of a measurement system in fluid communication with the first apparatus; measuring a first level of particles in the first sample by a liquid particle counter (LPC); after storing the first sample, storing a second sample of the liquid chemical from a second apparatus in fluid communication with the storage tank via the buffer tank, the second apparatus being different than the first apparatus; and measuring a second level of particles in the second sample by the LPC.

In some embodiments, a system is provided. The system includes: a storage tank operable to store a liquid chemical; a plurality of apparatuses in fluid communication with the storage tank; a liquid particle counter (LPC) operable to determine a level of particles in a sample of the liquid chemical; a buffer tank in fluid communication with the LPC and operable to store the sample; and a liquid selection apparatus in fluid communication with the plurality of apparatuses and the buffer tank, the liquid selection apparatus being operable to select one of the plurality of apparatuses and obtain the sample from the one.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method, comprising:
storing a liquid chemical in a storage tank;
supplying the liquid chemical from the storage tank to a semiconductor processing tool;
obtaining a first sample of the liquid chemical from a first apparatus in fluid communication with the storage tank via a liquid selection apparatus;
measuring a first level of particles in the first sample by a liquid particle counter (LPC);
after obtaining the first sample, obtaining a second sample of the liquid chemical from a second apparatus in fluid communication with the storage tank via the liquid selection apparatus, the second apparatus being different than the first apparatus; and
measuring a second level of particles in the second sample by the LPC.

2. The method of claim 1, comprising:
prior to obtaining the second sample, draining the first sample from the liquid selection apparatus and the LPC.

3. The method of claim 1, comprising prior to obtaining the second sample:
closing a first valve of the liquid selection apparatus associated with the first sample; and
opening a second valve of the liquid selection apparatus associated with the second sample.

4. The method of claim 1, comprising:
transferring the liquid chemical to the storage tank via an intake assembly in fluid communication with the storage tank;
transferring the liquid chemical from the storage tank to a supply assembly via a retrieval assembly in fluid communication with the storage tank and the supply assembly; and
feeding the liquid chemical from the storage tank back to the storage tank via a feedback assembly.

5. The method of claim 4, wherein:
obtaining the first sample includes opening a first valve of the liquid selection apparatus associated with the first apparatus of the intake assembly, the retrieval assembly, the supply assembly and the feedback assembly; and
obtaining the second sample includes opening a second valve of the liquid selection apparatus associated with the second apparatus of the intake assembly, the retrieval assembly, the supply assembly, and the feedback assembly, the second apparatus being different than the first apparatus.

6. The method of claim 1, comprising:
after obtaining the second sample, obtaining a third sample of the liquid chemical from a third apparatus in fluid communication with the storage tank via the liquid selection apparatus, the third apparatus being different than the first apparatus and the second apparatus; and
measuring a third level of particles in the third sample by a second LPC different than the LPC.

7. A method, comprising:
storing a liquid chemical in a storage tank;
storing a first sample of the liquid chemical from a first apparatus in fluid communication with the storage tank via a buffer tank of a measurement system in fluid communication with the first apparatus;
measuring a first level of particles in the first sample by a liquid particle counter (LPC);
after storing the first sample, storing a second sample of the liquid chemical from a second apparatus in fluid communication with the storage tank via the buffer tank, the second apparatus being different than the first apparatus; and
measuring a second level of particles in the second sample by the LPC.

8. The method of claim 7, comprising:
during measuring the first level, outputting the first sample of the liquid chemical to the LPC via a gas pressure pump in gas communication with the buffer tank.

9. The method of claim 8, wherein:
outputting the first sample includes supplying pressurized gas to the buffer tank by opening a pressure supply valve in gas communication with a gas supply.

10. The method of claim 7, comprising:
transferring the liquid chemical to the storage tank from a truck via an intake assembly in fluid communication with the storage tank;
transferring the liquid chemical from the storage tank to a supply assembly via a retrieval assembly in fluid communication with the storage tank and the supply assembly; and
filtering the liquid chemical from the storage tank via a feedback assembly.

11. The method of claim 10, wherein:
obtaining the first sample includes opening a first valve of a liquid selection apparatus associated with the first apparatus of the intake assembly, the retrieval assembly, the supply assembly and the feedback assembly, the liquid selection apparatus being in fluid communication with the intake assembly, the retrieval assembly, the supply assembly and the feedback assembly; and
obtaining the second sample includes opening a second valve of the liquid selection apparatus associated with the second apparatus of the intake assembly, the retrieval assembly, the supply assembly, and the feedback assembly, the second apparatus being different than the first apparatus.

12. The method of claim 11, wherein:
obtaining the first sample includes outputting the first sample via a mechanical pump of the first apparatus; and
obtaining the second sample includes outputting the second sample via a gas pressure pump of the second apparatus.

13. The method of claim 11, wherein:
obtaining the first sample includes opening a supply valve of the liquid selection apparatus, the supply valve being in fluid communication with the buffer tank; and
obtaining the second sample includes opening the supply valve.

14. The method of claim 13, comprising:
prior to obtaining the second sample, draining the liquid chemical from the liquid selection apparatus by opening a first drain valve of the liquid selection apparatus.

15. The method of claim 13, comprising prior to obtaining the second sample:
draining the liquid chemical from the LPC by opening a second drain valve in direct fluid communication with the LPC; and
draining the liquid chemical from the buffer tank by opening a third drain valve in direct fluid communication with the buffer tank.

16. A system, comprising:
a storage tank operable to store a liquid chemical;
a plurality of apparatuses in fluid communication with the storage tank;
a liquid particle counter (LPC) operable to determine a level of particles in a sample of the liquid chemical;
a buffer tank in fluid communication with the LPC and operable to store the sample; and
a liquid selection apparatus in fluid communication with the plurality of apparatuses and the buffer tank, the liquid selection apparatus being operable to select one of the plurality of apparatuses and obtain the sample from the one.

17. The system of claim 16, wherein the plurality of apparatuses comprises:
an intake assembly operable to transfer the liquid chemical to the storage tank from a tank external to the system;
a supply assembly operable to transfer the liquid chemical to a semiconductor processing tool external to the system; and
a retrieval assembly in fluid communication with the supply assembly, the retrieval assembly being operable to transfer the liquid chemical from the storage tank to the supply assembly.

18. The system of claim 16, wherein the liquid selection apparatus includes:
a plurality of first valves, each of the plurality of first valves being in fluid communication with a respective one of the plurality of apparatuses; and
a plurality of second valves, each of the plurality of second valves being in fluid communication with a respective one of the plurality of first valves.

19. The system of claim 18, wherein the liquid selection apparatus includes:
a supply valve in fluid communication with each of the plurality of second valves; and
a drain valve in fluid communication with each of the plurality of second valves.

20. The system of claim 16, wherein the buffer tank is operable to output the sample to the LPC via pressurized inert gas stored in the buffer tank.
